(19) United States
(12) Patent Application Publication
(10) Pub. No.: US 2007/0252283 A1
(43) Pub. Date: Nov. 1, 2007

(54) High speed, high density board to board interconnect

(76) Inventor: Christopher Lee Keller, Torrance, CA (US)

Correspondence Address: YING CHEN;Chen Yoshimura LLP, 255 S. GRAND AVE., # 215, LOS ANGELES, CA, 90012, US

(21) Appl. No.: 11/413,749

(22) Filed: Apr. 28, 2006

(51) Int. Cl. H01L 23/52

(52) U.S. Cl. 257/777

(57) ABSTRACT

A high speed, high density board to board interconnect structure uses a spacer board and BGA techniques to connect two circuit boards. The spacer board is a standard double-sided FR-4 printed circuit board and are connected to each of the circuit boards by a BGA. This interconnect structure allows high data rate to be passed from one board to another with a board to board spacing of about 1.5 mm. An example of the application of this technique is a 4 channel high speed (over 1 Gb/s) optical transceiver using 2 PCB substrates.

### BACKGROUND OF THE INVENTION

1. Field of the Invention

This invention relates to integrated circuit device packaging, and in particular, it relates to a high speed, high density board to board interconnect.

2. Description of the Related Art

This invention seeks to address three issues for an interconnection. The issues are high density, high speed, and small board to board mating height. Existing solutions can solve two of these problems but not all three simultaneously. There are solutions which use connectors that are for high density and high speed, but offer a minimum of 4 mm mated height. There are solutions that offer high density and 1.5 mm mated height, but do not offer high speed (see FIG. 5a, showing a transmitter board 110 and a receiver board 120 connected by a low speed connector 130). The tightest pitch on such board to board connectors is a 0.4 mm pitch, which allows 20 electrical connections in a space of about 30 mm², but they will not work at Gb/s speeds. Other traditional board to board interconnects such as pin grids and lead frames (see FIG. 5b, showing a transmitter board 110 and a receiver board 120 connected by a pin grid array or lead frame 140) are much too large and cannot handle the required density or board spacing of 1.5 mm. Standard ball grid array (BGA) connections allow the necessary bandwidth and density but do not allow the required spacing of 1.5 mm.

### SUMMARY OF THE INVENTION

There is a need for a connection that offers high density, high speed, and small board to board mating height at the same time. Embodiments of the present invention provide such a connection using BGA connections with a spacer board which allows the necessary gap between the boards.

An object of the present invention is to provide a high speed connector in a small area that will solve all three problems discussed above.

Additional features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, the present invention provides a board to board interconnect structure, which includes a first and a second circuit board disposed substantially in parallel; a spacer board disposed between the first and second circuit boards, the spacer board including an array of solder pads on each of a first and a second side thereof and an array of vias formed through the board to connect pairs of solder pads on the first and second sides; a first array of solder spheres electrically connecting the solder pads on the first side of the spacer board to the first circuit board; and a second array of solder spheres electrically connecting the solder pads on the second side of the spacer board to the second circuit board.

In another aspect, the present invention provides a method of manufacturing an integrated circuit device, which includes: providing a spacer board having an array of solder pads on each of a first and a second side thereof and an array of vias formed through the board to connect pairs of solder pads on the first and second sides; soldering a first side of the spacer board to a first circuit board using solder spheres; and soldering a second circuit board to the second side of the spacer board using solder spheres.

It is to be understood that both the foregoing general description and the following detailed description are exemplary and explanatory and are intended to provide further explanation of the invention as claimed.

### BRIEF DESCRIPTION OF THE DRAWINGS

FIG. 1 illustrates an optical transceiver according to an embodiment of the present invention.

FIG. 2 illustrates a board to board interconnect structure according to an embodiment of the present invention.

FIG. 3 illustrates the structure of the spacer in the embodiment of FIG. 2.

FIG. 4 illustrates a board to board interconnect structure according to another embodiment of the present invention.

FIGS. 5a and 5b illustrate conventional board to board interconnect structures.

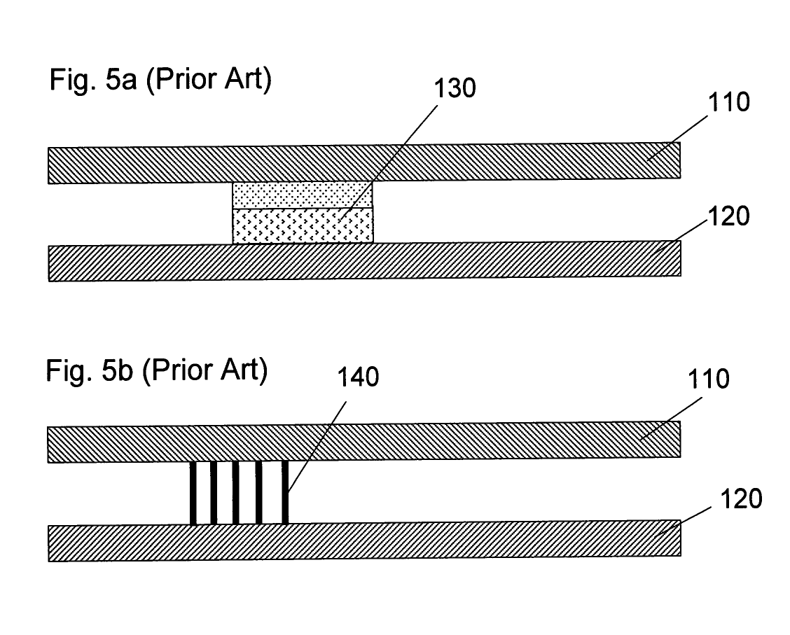

### DETAILED DESCRIPTION OF THE PREFERRED EMBODIMENTS

By using an electrical spacer board and BGA assembly techniques, a high speed connector can be achieve in a small area that will solve all three problems discussed above. Although in the following descriptions a transmitter board and a receiver board in a transceiver device are used to illustrate embodiments of the present invention, the invention can be used for connecting any suitable types of circuit members in any type of devices, including information handling devices, telecommunications devices, etc. The circuit members may be printed circuit boards, circuit modules, flex circuit, etc.

Embodiments of the present invention offer a high speed, high density board to board interconnect using a spacer board and ball grid array (BGA) packaging techniques that will allow high speed communication and small board to board spacing. In one particular example, the interconnect allows 4 channels of data at rates of over 1 Gb/s to be passed from one board to another, with a board to board spacing of only 1.5 mm. This allows the assembly of a 4-channel high speed optical transceiver using two printed circuit board (PCB) substrates.

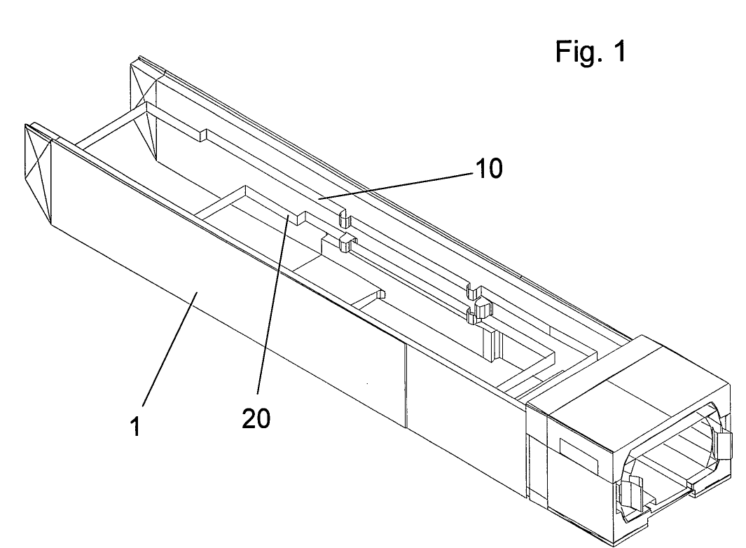

FIG. 1 shows the structure of an optical transceiver according to an embodiment of the present invention. The transceiver 1 includes a transmitter board 10 and a receiver board 20, which are PCBs in this example, in an enclosure. The transmitter board 10 and the receiver board 20 are disposed substantially in parallel and connected by a spacer board (not shown). In one particular example, the transceiver has approximate dimensions of 69 mm in length, 13.3 mm in width and 9.4 mm in height.

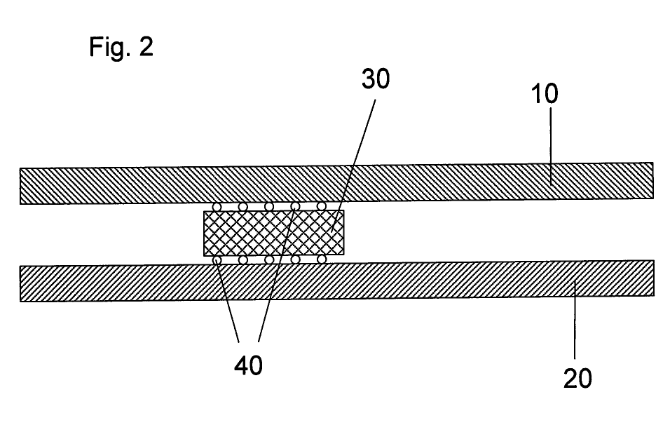

FIG. 2 is a schematic cross-sectional view showing the transmitter board 10 and receiver board 20 connected by the spacer board 30. The transmitter board 10 and receiver board 20 are connected to the spacer board 30 by solder spheres 40 forming a BGA. The spacer board 30 is preferably a PCB, such as a standard double-sided FR-4 PCB. The spacer board can also be made of other materials, such as other more application specific PCB materials (FR5), plastic or other polymer materials, etc. This allows the flexibility in the board to board spacing and achieves a board spacing of as small as 1.5 mm. In the particular example, the transmitter board and receiver board are approximately 11 mm in width and the board spacing is 1.5 mm.

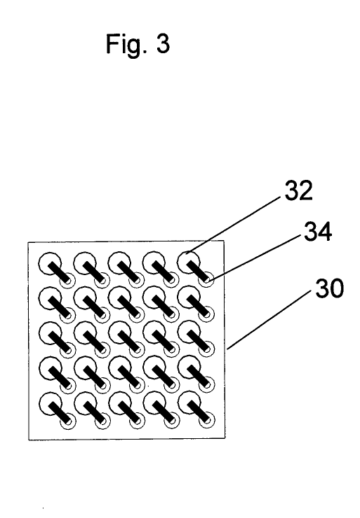

FIG. 3 shows the spacer board 30 and the layout of the BGA pads on one of its side surfaces. Each pad 32 is connected to a pad on the other side of the spacer board by a via 34. Because of the need for high speed data transmission it is preferable to surround the vias with ground. This helps with both impedance matching and crosstalk minimization. In this particular example, the size of the spacer board is 0.2218 by 0.2218 inches, and the distance between adjacent rows or columns of solder pads 32 is 0.0394 inches. A 5×5 BGA grid is used to achieve the necessary number of connections. Depending on the data transmission need, a number of pads may be used for data transmission and the remaining vias may be grounded.

To assemble the transmitter and received boards, the spacer board 30 is first soldered to the transmitter board 10 using solder spheres and then the receiver board 20 is soldered to the spacer board. This allows a very reliable connection that can be assembled with standard reflow technology.

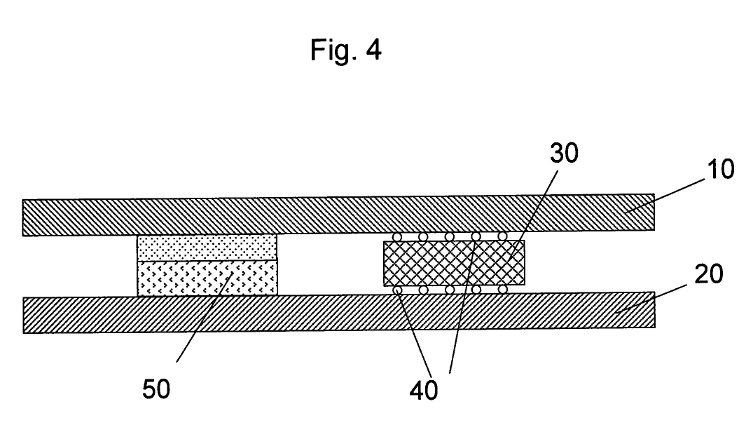

The spacer board 30 may be used in combination with other connector structures. In an example shown in FIG. 4, the high speed spacer board 30 is used in combination with a low speed connector 50, which is a 30 pin board to board connector available from AVX Corporation in this example. Other suitable low speed connectors may be used in such a combination structure. The low speed connecter 50 also functions in automatic alignment. In a particular example of such a configuration, the board to board spacing of the interconnect structure is 1.5 mm.

By using a spacer board and a BGA according to embodiments of the present invention, a high density optical transceiver can be achieved to fit 4 channels of data in the same footprint used for current single channel transceivers.

It will be apparent to those skilled in the art that various modification and variations can be made in the high speed, high density board to board interconnect of the present invention without departing from the spirit or scope of the invention. Thus, it is intended that the present invention cover modifications and variations that come within the scope of the appended claims and their equivalents.

What is claimed is:

1. A board to board interconnect structure comprising:
a first and a second circuit board disposed substantially in parallel;
a spacer board disposed between the first and second circuit boards, the spacer board including an array of solder pads on each of a first and a second side thereof and an array of vias formed through the board to connect pairs of solder pads on the first and second sides;
a first array of solder spheres electrically connecting the solder pads on the first side of the spacer board to the first circuit board; and
a second array of solder spheres electrically connecting the solder pads on the second side of the spacer board to the second circuit board.

2. The interconnect structure of claim 1, wherein the spacer board is a double-sided FR-4 printed circuit board.

3. The interconnect structure of claim 1, wherein the spacer board is made of a polymer material.

4. The interconnect structure of claim 1, wherein a board to board spacing between the first and second circuit boards is about 1.5 mm.

5. The interconnect structure of claim 1, wherein the vias are surrounded with ground.

6. The interconnect structure of claim 1, wherein the first and second circuit boards are printed circuit boards.

7. The interconnect structure of claim 1, wherein the first circuit board is a transmitter board and the second circuit board is a received board, the first and second circuit boards being interconnected to each other to from a transceiver device.

8. The interconnect structure of claim 1, further comprising a second connector between the first and second circuit boards.

9. A method of manufacturing an integrated circuit device, comprising:
providing a spacer board having an array of solder pads on each of a first and a second side thereof and an array of vias formed through the board to connect pairs of solder pads on the first and second sides;
soldering a first side of the spacer board to a first circuit board using solder spheres; and
soldering a second circuit board to the second side of the spacer board using solder spheres.

10. The method of claim 9, wherein the spacer board is a double-sided FR-4 printed circuit board.

11. The method of claim 9, wherein the spacer board is made of a polymer material.

12. The method of claim 9, wherein a board to board spacing between the first and second circuit boards is about 1.5 mm.

13. The method of claim 9, wherein the vias are surrounded with ground.

14. The method of claim 9, wherein the first and second circuit boards are printed circuit boards.
